(19) United States
(12) Patent Application Publication
(10) Pub. No.: US 2009/0244948 A1
(43) Pub. Date: Oct. 1, 2009

(54) EMBEDDED MEMORY APPARATUS WITH REDUCED POWER RING AREA

(75) Inventors: PANG-YEN HUNG, TAIPEI (TW); JIAN-LIANG CHEN, TAIPEI (TW)

Correspondence Address: ROSENBERG, KLEIN & LEE, 3458 ELLICOTT CENTER DRIVE-SUITE 101, ELLICOTT CITY, MD, 21043, US

(73) Assignee: ALI CORPORATION, TAIPEI (TW)

(21) Appl. No.: 12/182,412

(22) Filed: Jul. 30, 2008

(30) Foreign Application Priority Data
Mar. 25, 2008 (CN) 200810087929.7

(51) Int. Cl. G11C 5/02; G11C 5/14

(52) U.S. Cl. 365/51; 365/226

(57) ABSTRACT

An embedded memory apparatus with reduced power ring area is disclosed. In order to save the area consumption of a chip, a scheme for removing the power rings originally disposed in a memory core, or another scheme for sharing the power rings with other adjacent memory cores is provided. According to the preferred embodiment of the routing, the power strips originally bridging the inner elements and the outer power serve as the power source (VDD) and ground (VSS) respectively since the peripheral power ring surrounded the core is removed. Thus the area consumption is reduced as if the surrounded power ring shrinks inwardly. The shared power ring for the adjacent memory cores can also be another aspect for reducing the area.

### BACKGROUND OF THE INVENTION

1. Field of the Invention

The present invention relates to a memory apparatus, more particularly to a memory apparatus with inwardly shrunk power strips or with a shared memory power ring disposed between the adjacent elements, so as to reduce the size of its occupying area.

2. Description of Related Art

With the development of the technology of the System-On-Chip (SOC), the related manufacturing process advances to a nano scale or deep sub-micron scale process, so that the embedded memory occupies a larger portion of the chip's area. Since portable electronic products, such as the digital music player (MP3 player) or portable media player (PMP), become widespread, the key of IC design tends to implement low-voltage and low-power consumption.

In general, the work frequency of the chip will affect the size of the power ring of the embedded memory. The smallest preset width of the power ring still occupies a portion of the chip area even though the chip operates in an extreme low frequency.

The memory embedded in a chip of the conventional technology is shown in FIG. 1, which shows a schematic diagram of the circuitry layout of a memory core. The dotted line encircles the circuit of the memory core, which is fabricated mainly by stacking an oxide layer (OD), poly silicon (POLY) and a plurality of metal layers. The major compositions of the memory core are the stacks of poly silicon and oxide layer shown as the under structure 10 of this diagram, for example, the MOS transistors and the diodes are fabricated as the core. Further, this diagram shows the circuitry layout of the two major metal layers, such as a third metal layer M3 and a fourth metal layer M4 indicated by different sectional lines. In which, a power ring 15 surrounding the memory core is mounted on a top metal layer Mx, such as the fourth metal layer M4 referring to FIG. 2 shown in current example. The third metal layer M3 and the fourth metal layer M4 are formed as a power source (VDD) and a ground (VSS) respectively, and forming the power supplying all the interior elements.

Furthermore, the inner power structure of the memory core, such as the top two metal layers, has meshed power strips 13 formed by the third metal layer M3 and the fourth metal layer M4. In order to connect to the external power source, the power strips 13 extend to the margin of the core, and connect to the power ring 15 disposed on the fourth metal layer M4 via a via array 11, as the black dots shown in the diagram.

Reference is made to FIG. 2 showing the cross-sectional view of the structure of memory core. In which, a plurality of layers are included. This structure has a bottom oxide layer OD, a poly silicon layer, a first metal layer M1, a second metal layer M2, a third metal layer M3 and a fourth metal layer M4. Corresponding to the structure shown in FIG. 1, the power ring 15 merely surrounds the peripheral area of the fourth metal layer M4 to form the VDD and VSS of the chip. Furthermore, the terminal of components of each memory core connects with each other via the metal layers M1 and M2, and the metal layers M5 and M6 are provided for other applications.

FIG. 3 shows a schematic diagram of the memories lined up in a chip. In general, the working frequency of the memory core primarily dominates the width of the power ring, so that a higher frequency should require a larger width of the power ring for obtaining sufficient power supply for every element in the core. The width of power ring is about a few micrometers to 10 or more micrometers in normal use, but the width will be doubled if the power source and the ground are separately arranged. This exemplary embedded memory shown in the drawing is used in a systematized chip, and the memory cores 30 are arranged in a block very closely. There are two power rings surrounding the memory cores 30 and forming the VDD and VSS respectively. Besides the major circuits of the cores, the power ring and the ground ring also occupy a portion of the area.

### SUMMARY OF THE INVENTION

In view of the conventional power ring used for the memory in a chip, the size of the power ring is determined in accordance with the systematic work frequency, and the width of the power ring will take up a portion of the chip area even in a very low frequency. In order to save the use of the chip area, the present invention provides an embedded memory apparatus with reduced power ring area. Particularly, according to the preferred embodiment, the area consumption can be reduced in order to save the memory area used in the chip. In which, the power rings outside the memory core are removed in condition for meeting the requirement of the timing and IR drop.

The one of the objectives of the present invention is straightforward to remove the power rings outside the memory cores. Preferably, the power rings outside the memory cores are removed during the circuitry routing process. Therefore, the power strips originally bridging the inner elements and the outside power source are further used to function as the power source (VDD) and ground (VSS). The new application of the power strips is similar with the outside power ring shrunk (extended) inwardly for reducing the area occupied by the memory apparatus.

Another objective of the present invention is using the shared power ring between the adjacent memory cores for reducing the chip area.

According to one objective of the present invention, a guard ring is disposed outside the memory cores in addition to removing the outside power ring for preventing the external interference.

Another objective of the present invention is to remove the power rings between the adjacent memory cores but to keep the outer power ring of the block formed by the memory cores. Accordingly, the embodiment is not only reducing the area consumption, but also keeping the function of a guard ring.

The last objective of the present invention is to keep the outer power ring disposed on the side close to the high interference source, but the power ring on the other sides is shrunk or used as the shared power rings.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 shows a top view of design diagram of the memory embedded in a chip of the prior art;

FIG. 2 shows a lateral view of another design diagram of the memory embedded in a chip of the prior art;

FIG. 3 shows a schematic diagram of the memories lined up in a chip of the prior art;

FIGS. 4a and 4b show the schematic diagrams of the circuitry layout of a chip;

FIGS. 5a and 5b are the schematic diagrams showing the area changes before and after removing the memory power rings;

FIGS. 6a and 6b are the lateral views of the structure before and after removing the power rings;

FIG. 7 shows a schematic diagram of the power rings shared with the adjacent memory blocks of an embodiment of the invention;

FIG. 8 shows a schematic diagram of a guard ring surrounding the memory blocks of the embodiment of the invention;

FIG. 9 is a schematic diagram showing a power ring disposed outside the memory blocks of the embodiment of the invention;

FIG. 10 is a schematic diagram showing a power ring disposed on one side of the memory blocks of the embodiment of the invention.

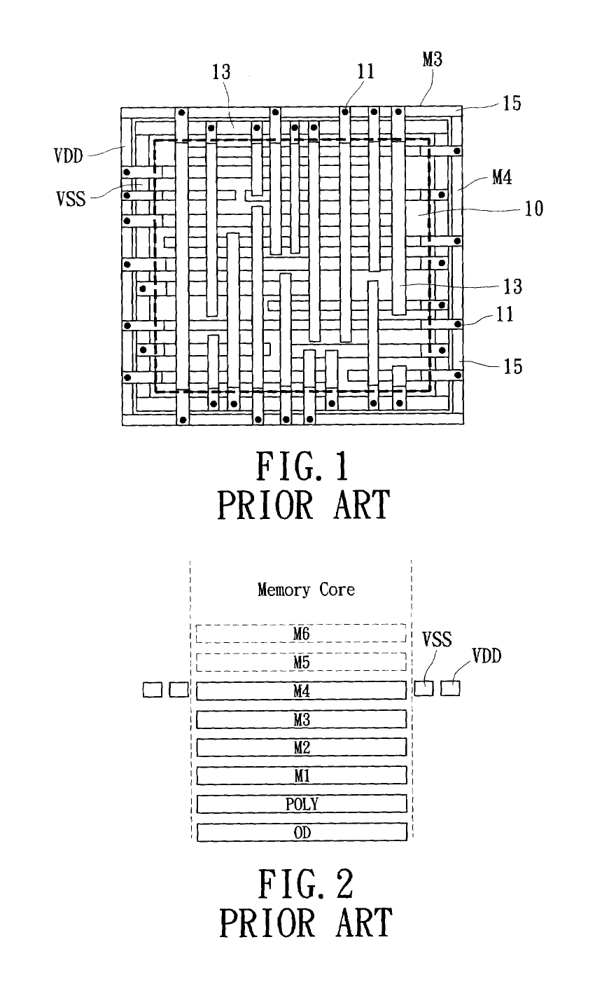

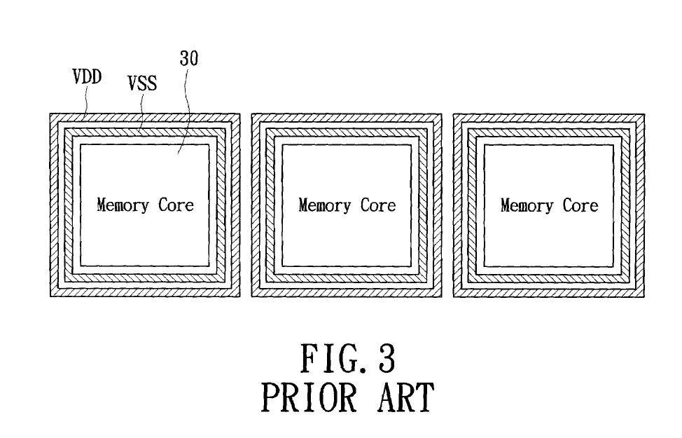

### DETAILED DESCRIPTION OF THE PREFERRED EMBODIMENTS

The present invention is illustrated with a preferred embodiment and attached drawings. However, the invention is not intended to be limited thereby.

The present invention provides a layout of a chip that can reduce the area consumption of the embedded memory. Particularly, it's still content with the requirement of the systematic timing and IR drop while the power rings used for the memory are preferably removed or reduced for shrinking the area use of the chip. The above approach is especially used for the portable electronic products such as the digital media player or the portable computer.

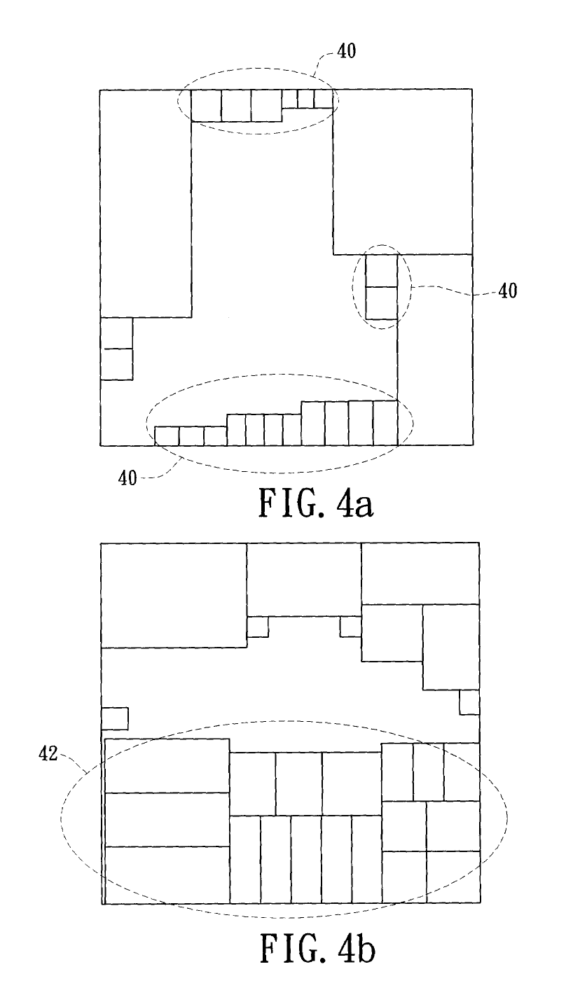

Reference is made to FIG. 4a showing a schematic diagram of the circuitry layout of a chip. The blocks are presented as the elements of the chip layout. The circled numeral 40 shows the block formed by a plurality of memory cores. The determination of the area occupied by the memory block 40 is depending on design. Since the manufacturing process has progressed to nanometer or deep sub-micron scale, the memory block 40 is relatively occupies larger area in the chip due to the elements becoming smaller. Referring to FIG. 4b, the circled memory block 42 has larger portion of the area, that is, the area of whole chip can be smaller if the area occupied by the embedded memory can be efficiently decreased. Therefore, the present invention has the advantage since it removes the power ring and uses the shared power ring in order to reduce the area consumption.

Type 1:

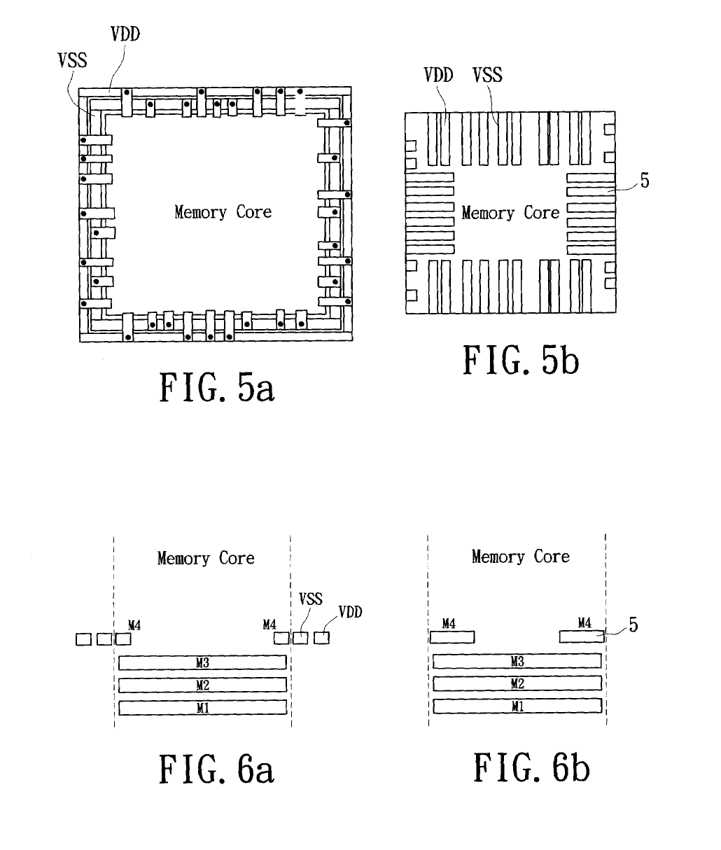

FIG. 5a shows a schematic diagram of the conventional memory core with peripheral power ring, and particularly, FIG. 5b shows the embodiment of the memory core after removing the peripheral power ring. Accordingly, the embodiment of the memory core without the peripheral power ring is to remove the power ring structure outside the memory core. The power ring connects to the power lines extending from inner elements to outside portion. Particularly, the structure of the power ring surrounding the memory core is removed when preparing the circuitry layout according to the embodiment. After that, merely a small portion of the inner circuitry can connect to the outer circuitry, as shown in the cross-sectional diagrams of FIGS. 6a and 6b.

Such as the diagram shown in FIG. 5a, there is a plurality of layers disposed in the conventional memory core, and its power ring is mounted on a top metal layer. Further in FIG. 5b, the power rings forming the power source (VDD) and the ground (VSS) are removed in the present invention. Without affecting the original function, the structure of the original power source and ground is extended to the core, and the power strips 5 bridging the inner elements and the outer power source function as VDD and VSS. In which, the power strips 5 still connect with other layers via the vias. Therefore, a certain area can be reduced in a single memory core, and the reduced area is also different since the width of the power ring is designed in accordance with the memory size

References are made to FIG. 6a and FIG. 6b. FIG. 6a shows a cross-sectional view of the conventional memory core with two peripheral power rings, which form the power source (VDD) and ground (VSS) surrounding the fourth metal layer M4. FIG. 6b shows a cross-sectional view of an embodiment of the present invention, featuring the memory core without the peripheral power ring. In the present invention, there are several embodiments showing how the metal layer extends to the core in accordance with the memory types after removing the power rings. In particular, the extension of the metal layer is like the peripheral power ring shrinking inwardly to the core.

Furthermore, in order to reduce the chip area, it still needs to overcome some drawbacks such as the space occupied by the shrunk portion will use the resources originally for other elements. In the current example, the area of fourth metal layer M4 equivalent to the area of the removed power rings will occupy the routing resource above the memory core. It needs to balance the selective extended length and the routing resource.

Type 2:

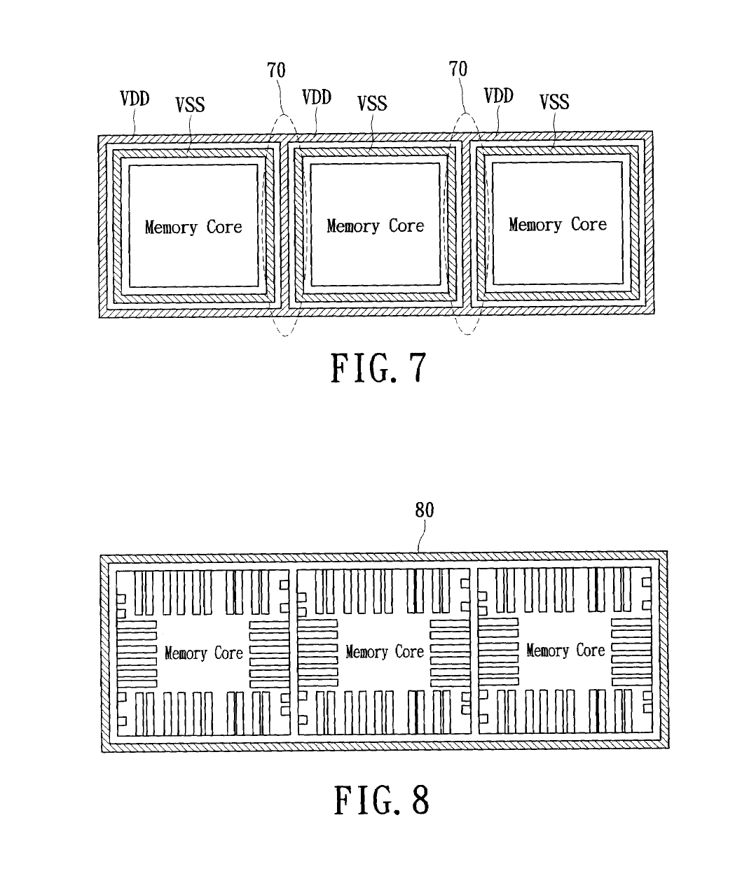

In addition to reducing the area consumption of the aforementioned structure by removing the power rings, a scheme using the shared power rings between the adjacent elements is also used. Reference is made to FIG. 7 showing a schematic diagram of the shared power ring of the preferred embodiment. The shown power rings disposed between the memory cores are the shared power rings 70 overlap with each other. In the structure on the same layer, a plurality of power strips is included besides the original peripheral power ring. The power strips extend to the margin of the memory core, and connect to the peripheral power ring via a plurality of vias. In the normal memory structure, the power ring is the structure with two-layer (two-part) design. The structure is centered on the core circuitry, and an outward-extended first layer is a ground ring (VSS), and a power ring (VDD) is disposed more outwardly. Because of the systematization of chip, the memory cores will be arranged very close to the chip's margin. Such as the blocks shown in FIG. 7, since the blocks are arranged very closely, the power ring of a memory core overlaps the other power ring of the adjacent memory core. The overlapped power rings are equivalent to the shared power rings 70 for the purpose of area reduction.

Furthermore, if the power ring can function as a guard ring, the power ring can surround the memory core completely, or merely be disposed on a side close to the interference source.

Type 3:

The aforementioned schemes are to remove the power ring, or to reduce the area occupied by the power ring, but the embodiment shown in FIG. 8 depicts that not only the power ring is used to deliver power to the inner elements, but also be the guard ring for resisting the external interference, especially for the interference from digital signals. In the diagram, three memory cores without power rings are arranged in a row. In order to keep the isolation functioned from the original power ring, a guard ring 80 surrounding the memory cores is disposed peripherally for resisting the outer interference. The shown guard ring is not necessary to surround the cores completely, but can be partly surrounded, or disposed on one side close to the interference source.

Type 4:

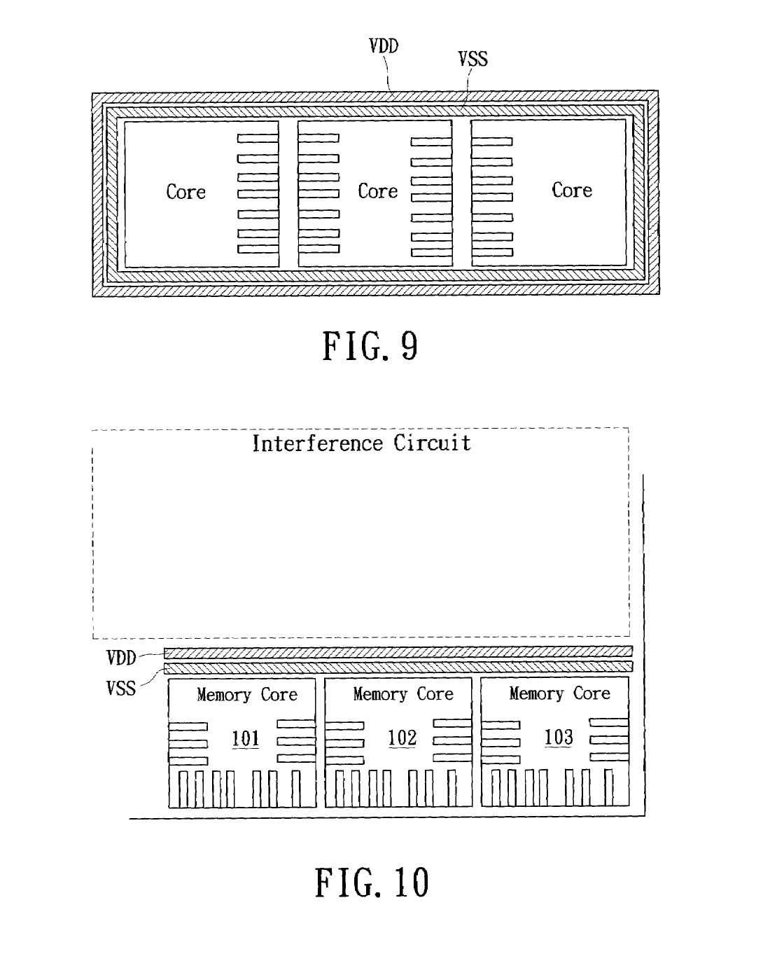

FIG. 9 shows another embodiment of the present invention. The peripheral power ring surrounding the block formed by the outer power cores (can be more than three cores) can be kept as shown. In which, the most peripheral power ring (VDD) and ground ring (VSS) are kept but the power rings disposed between the memory cores are removed. Therefore, the most peripheral power ring can function as the guard ring, and the portions of the power source and ground are shrunk just like above description as removing the power rings therebetween.

According to another embodiment, the power ring with function of the guard ring can be disposed on one side of the memory apparatus close to the interference source.

Type 5:

The memory cores are always disposed near the margin in chip design. Since the memory block will not be influenced by the four-directional interferences simultaneously, only the power ring disposed on the side close to the high interference is kept. Reference is made to FIG. 10, the memory cores 101, 102, 103 are disposed on the lower right corner of the chip, and the upside circuit forms the interference source. Therefore, only the power ring disposed on the upside of the memory block is kept for resisting the interference. The power rings originally disposed on the other sides of the memory block can be shrunk or used to be the shared power ring.

The above-mentioned embodiments regarding the power ring, guard ring and the arrangement of the memory cores can be manufactured for the purpose of reducing the area occupied by the chip by minimizing the use of power rings.

In summation of the above description, the embedded memory apparatus with reduced power ring area of the present invention can as implemented by shrinking the power rings, or using shared power rings between the adjacent memories for reducing the area use of the chip.

While the invention has been described by means of a specification with accompanying drawings of specific embodiments, numerous modifications and variations could be made thereto by those skilled in the art without departing from the scope and spirit of the invention set forth in the claims.

What is claimed is:

1. An embedded memory apparatus having a plurality of layers,
wherein a peripheral power ring of the memory apparatus is removed for reducing the area of the memory apparatus embedded in a chip, characterized in that:
at least one memory core and a plurality of power strips are disposed in the embedded memory apparatus, and the power strips are mounted on a metal layer of the top layer of the memory core, wherein the power strips stretch from the margin to the interior and electrically connect with other layers via a plurality of vias to act as power terminals and ground terminals of the embedded memory apparatus.

2. The embedded memory apparatus of claim 1, wherein the periphery of the memory core further includes a guard ring surrounding the embedded memory apparatus for reducing electrical interference.

3. The embedded memory apparatus of claim 1, wherein the periphery of the memory core further includes a portion of the surrounding guard ring that is disposed at one side close to an interference source.

4. An embedded memory apparatus having a plurality of layers,
wherein shared power rings are used for reducing the area of the memory apparatus embedded in a chip, characterized in that:
the embedded memory apparatus includes a plurality of memory cores, wherein a shared power ring is mounted on the adjacent part between the memory cores, and a peripheral power ring is disposed on the most outer area of the memory cores; the shared power ring, the peripheral power ring and the plurality of power strips are mounted on the same metal layer, wherein the power strips extend to the margin of the memory cores, and electrically connect with the power ring via a plurality of vias.

5. The embedded memory apparatus of claim 4, wherein the peripheral power ring surrounds the memory cores completely or partly.

6. The embedded memory apparatus of claim 4, wherein the peripheral power ring partly surrounds a side of the memory cores close to an interference source.

7. An embedded memory apparatus with reduced area use of a chip by removing the power ring disposed between the adjacent memory cores, characterized in that:
the embedded memory apparatus includes a plurality of the memory cores, and each memory core has a plurality of layers; a peripheral power ring surrounds the outer area of the memory cores and the power rings between the memory cores are removed; the peripheral power ring and a plurality power strips are mounted on the same metal layer, and the power strips extend to the margin of the memory cores; and the power strips and the peripheral power ring are connected via a plurality of vias.

8. The embedded memory apparatus of claim 7, wherein the peripheral power ring surrounds the memory cores completely or partly.

9. The embedded memory apparatus of claim 7, wherein the peripheral power ring partly surrounds a side of the memory cores close to an interference source.

10. The embedded memory apparatus of claim 7, wherein the inwardly shrunk power strips substitute the removed power rings which originally disposed on the adjacent part of the memory cores.
